(19) United States
(12) Patent Application Publication
(10) Pub. No.: US 2026/0150267 A1
(43) Pub. Date: May 28, 2026

(54) MEMORY ARRAY INCLUDING ENLARGED ACTIVE AREA

(71) Applicant: Micron Technology, Inc., Boise, ID (US)

(72) Inventors: Bojing YAO, Boise, ID (US); Song GUO, Boise, ID (US)

(21) Appl. No.: 19/338,370

(22) Filed: Sep. 24, 2025

Related U.S. Application Data
(60) Provisional application No. 63/723,991, filed on Nov. 22, 2024.

(51) Int. Cl. H10B 12/00

(52) U.S. Cl. CPC H10B 12/34; H10B 12/02; H10B 12/482; H10B 12/485; H10B 12/488

(57) ABSTRACT

Implementations described herein relate to various structures, integrated assemblies, and memory devices. In some implementations, an integrated assembly includes a shaped semiconductive region. The shaped semiconductive region includes a first approximately trapezoidal end region, a second approximately trapezoidal end region, and a mid-region extending between the first approximately trapezoidal end region and the second approximately trapezoidal end region. The mid-region may have a width in a direction that is less than a width of the first approximately trapezoidal end region and the second approximately trapezoidal end region in the direction.

### CROSS-REFERENCE TO RELATED APPLICATION

This Patent Application claims priority to U.S. Provisional Patent Application No. 63/723,991, filed on November 22, 2024, entitled “MEMORY ARRAY INCLUDING ENLARGED ACTIVE AREA ,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a semiconductor device including a memory array including an enlarged active area.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell described herein.

FIGS. 2A and 2B are diagrammatic views of an example memory array described herein.

FIG. 3 is a flowchart of an example method of forming an integrated assembly or memory device having an array of shaped semiconductive regions described herein.

FIGS. 4A-4E are diagrammatic views showing formation of an array of shaped semiconductive regions described herein at stages of an example process of forming the array.

FIGS. 5A and 5B are diagrammatic views showing formation of an array of elongated semiconductive regions having an alternating width pattern at stages of an example process of forming the array of elongated semiconductive regions.

FIG. 6 is a diagrammatic view of an example memory device described herein.

### DETAILED DESCRIPTION

In the field of semiconductors, the demand for higher density and better-performing memory devices challenges engineers and designers to push the limits of manufacturing technologies. Increasing pattern density in memory cells, such as dynamic random access memory (DRAM) memory cells, is a goal to achieving higher memory capacity within a limited space. However, the integration of these dense patterns introduces complex technical issues. The process demands control over the critical dimensions (CDs) to maintain cell integrity and performance. High pattern density can result in mechanical stresses, potential defects, and process variations that lead to yield reduction and diminished mechanical stability of the memory cells. As manufacturing technologies scale down to meet the requirements of advanced electronic devices, such limitations become even more pronounced.

Some implementations described herein include a memory structure with larger active areas (e.g., critical dimensions (CDs)) as manufacturing technologies scale to accommodate higher density patterns. In some implementations, each of the active areas consists of opposing semiconductive regions (e.g., cell contact landing areas) that have widened end regions and a narrower mid-region (e.g., bit line contact landing areas). A memory array including multiples of the active area may be patterned in such a way that the mid-regions of adjacent active areas are spaced at a distance that allows for maintaining and/or increasing the widths of active areas.

In some implementations, a method to achieve the memory array includes forming an array of elongated semiconductive regions with alternating width patterns that interleave with one another, and cutting the elongated semiconductive regions to form active areas. Forming the array of elongated semiconductive regions may include using one or more of a trimming, reverse pitch doubling, inverse hole pitch doubling, and/or a pattern transferring technique. Furthermore, and after formation, the active areas may reflect a “dumbbell-shaped” design.

In these ways, the techniques address issues associated with scaling down memory cells in high pattern density manufacturing. The introduction of the shaped active areas may maintain and/or increase widths of active area contact regions within the memory array, reduce stress-related defects during etching and filling processes used to form the memory array, and improve yield rates and device performance consistency in scaled memory architectures. Furthermore, the configuration of the active areas and the STI regions may facilitate electrical isolation and ensure higher reliability, thereby improving a quality and/or a reliability of the memory cell. As a result of improving the quality and/or the reliability, an amount of resources used to support a market consuming the semiconductor device (e.g., raw materials, semiconductor manufacturing tools, labor, and/or computing resources) is reduced.

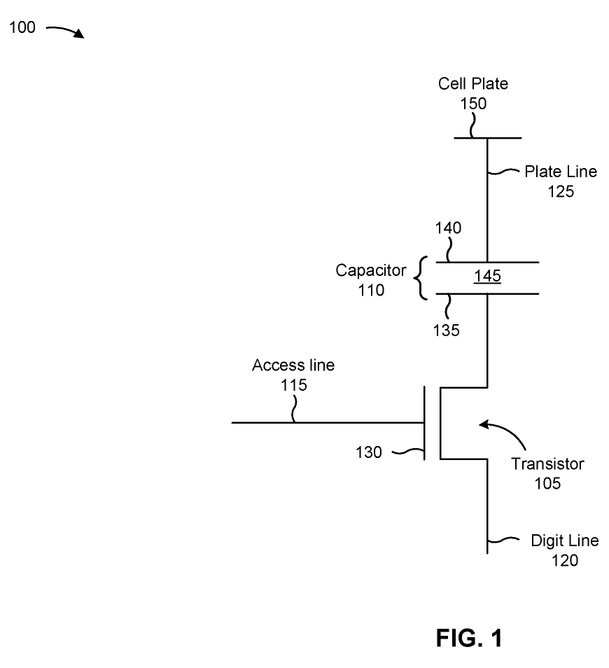

FIG. 1 is a circuit diagram of an example memory cell 100 described herein. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the digit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

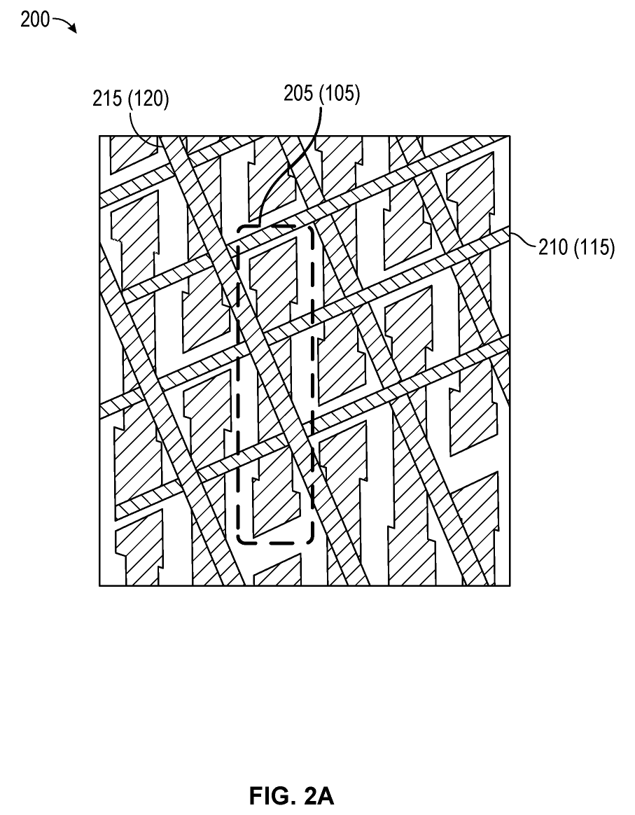

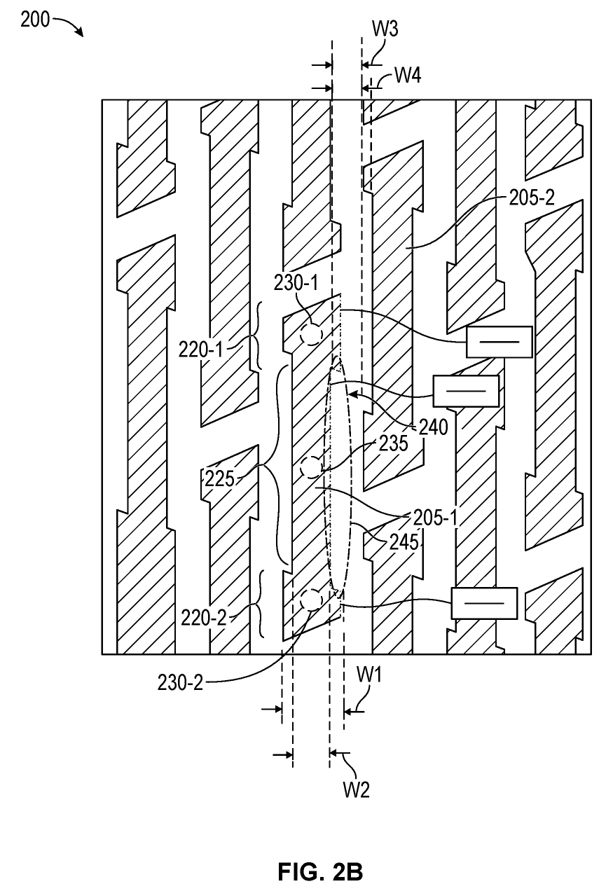

As described in greater detail in connection with FIG. 2A through FIG. 6, in some implementations, a memory array may include multiples of the memory cell 100. The memory array may include an array of active areas that each correspond to a channel of the transistor 105. Each active area may include opposing end regions and a mid-region, where a width of the mid-region is narrower than a width of the opposing end regions. A width pattern of the active areas (e.g., including mid-regions having the narrower width) enables maintaining and/or increasing widths of active area regions as manufacturing technologies scale to smaller and smaller geometries.

As indicated above, FIG. 1 is provided as an example. Other examples may differ from what is described with respect to FIG. 1.

FIGS. 2A and 2B are diagrammatic views of an example memory array 200 described herein. The diagrammatic views include plane views of the memory array 200.

As shown in FIG. 2A, the memory array 200 includes at least one shaped semiconductive region 205. The shaped semiconductive region 205 (e.g., corresponding to an active area and/or a channel of the transistor 105 of a memory cell 100 as described in connection with FIG. 1) may be a semiconductor and may comprise, consist of, or consist essentially of semiconductive material. The semiconductive material may comprise, consist of, or consist essentially of silicon (e.g., polycrystalline silicon), among other examples.

As further shown in FIG. 2A, the memory array 200 includes at least one conductive line 210 that extends across the shaped semiconductive region 205 in a first direction. The conductive line 210 (e.g., corresponding to an access line 115 of a memory cell 100 as described in connection with FIG. 1) may be an electrical conductor and may comprise, consist of, or consist essentially of conductive material. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples.

As further shown in FIG. 2A, the memory array 200 includes at least one conductive line 215 that extends across the shaped semiconductive region 205 in a second direction that is approximately orthogonal to the first direction. In other words, the conductive line 215 may be approximately orthogonal to the conductive line 210. The conductive line 215 (e.g., corresponding to a digit line 120 of a memory cell 100 as described in connection with FIG. 1) may be an electrical conductor and may comprise, consist of, or consist essentially of conductive material. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples.

FIG. 2B shows additional details of the memory array 200, including aspects of an array of shaped semiconductive regions 205 (e.g., an array of active areas) including the shaped semiconductive region 205-1 and the shaped semiconductive region 205-2. As shown in FIG. 2B, the shaped semiconductive region 205-2 is adjacent to and staggered with respect to the shaped semiconductive region 205-1. Furthermore, the shaped semiconductive region 205-2 is approximately parallel to the shaped semiconductive region 205-1. FIG. 2B excludes the conductive lines 210 and 215 for clarity.

As shown in FIG. 2B, the shaped semiconductive region 205-1 includes an end region 220-1 and an end region 220-2 (e.g., opposing end regions). In some implementations, the end region 220-1 and the end region 220-2 may each have an approximately trapezoidal shape (e.g., in other words, the end region 220-1 and the end region 220-2 may each be a trapezoidal end region). The approximately trapezoidal shape may, in some implementations, have rounded corners. Furthermore, in some implementations, the end region 220-1 and the end region 220-2 may have orientations that mirror one another. For example, and as shown in FIG. 2B, the orientation of the end region 220-2 mirrors the orientation of the end region 220-1. As used herein, an approximately trapezoidal shape may refer to a shape that is a trapezoid with straight edges and angular corners, a shape that is a trapezoid except for one or more rounded corners, or a shape that otherwise approximates a trapezoid (e.g., with one or more curved or rounded corners, one or more edges that are slightly curved or otherwise not entirely straight, or the like).

A mid-region 225 extends between the end region 220-1 and the end region 220-2. In some implementation, the end region 220-1 is a region for a cell contact landing 230-1 and the end region 220-2 is a region for a cell contact landing 230-2. The cell contact landing 230-1 and/or the cell contact landing 230-2 may each be a landing for a contact that electrically couples the shaped semiconductive region 205-1 to a capacitor of a memory cell (e.g., capacitor 110 of the memory cell 100 of FIG. 1).

As shown in FIG. 2A, the mid-region 225 may have an approximately rectangular shape. In some implementations, the mid-region 225 is a bit contact landing 235. The bit contact landing 235 may be a landing for a contact that electrically couples the shaped semiconductive region 205-1 to a bit line of one or more respective memory cells (e.g., the digit line 120 of the memory cell 100 of FIG. 1).

As further shown in FIG. 2B, an insulative region 240 (e.g., a shallow trench isolation region) may be between the shaped semiconductive region 205-1 and the shaped semiconductive region 205-2. The insulative region 240 may be an electrical insulator and may comprise, consist of, or consist essentially of insulative material. The insulative material may comprise, consist of, or consist essentially of silicon dioxide and/or silicon nitride, among other examples.

In some implementations, the insulative region 240 is along a contour of the shaped semiconductive region 205-1 (and/or a corresponding contour of the shaped semiconductive region 205-2). As an example, and as shown in FIG. 2B, the insulative region 240 includes an approximately linear sidewall along the end region 220-1, an approximately linear sidewall along the end region 220-2, and an approximately linear sidewall along the mid-region 225. Additionally, or alternatively and as shown in FIG. 2B, at least a portion of the insulative region 240 occupies a recessed portion 245 of the shaped semiconductive region 205-1 along the mid-region 225.

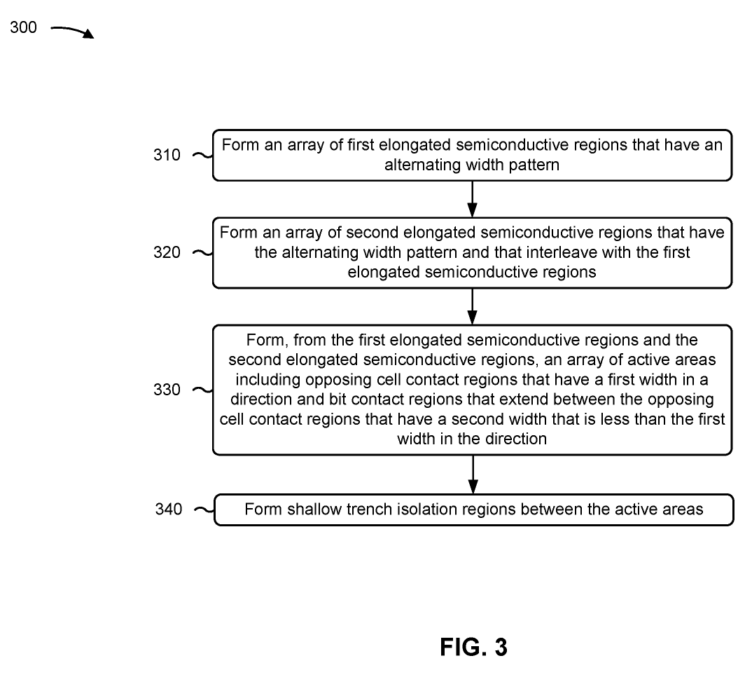

As described in greater detail in connection with FIG. 3 through FIG. 5B, the shaped semiconductive region 205-1 may be fabricated to have one or more dimensional properties and/or characteristics. In some implementations, the mid-region 225 of the shaped semiconductive region 205-1 has a width W1 along a direction (e.g., a lateral width) and the end region 220-1 has a width W2 along the same direction, where W1 is less than W2. For example, the width W1 may be included in a range of approximately 10.5 nanometers (nm) to approximately 11.5 nm, and the width W2 may be included in range of approximately 12.5 nm to approximately 13.5 n.

Additionally, or alternatively, a ratio of the width W2 to the width W1 (W2:W1) may be greater than approximately 1. If the ratio W2:W1 is greater than approximately 1, a width of the insulative region 240 may be maintained and/or increased for a particular manufacturing technology node (e.g., patterning line width) to reduce stress-related defects during etching and filling processes used to form the insulative region 240. Furthermore, the configuration of the insulative region 240 may facilitate electrical isolation of the semiconductive regions 205-1 and 205-2 to ensure electrical performance, thereby improving a quality and/or a reliability of a semiconductor device including the memory array 200. If the ratio W2:W1 is less than, or approximately equal to 1, such benefits may not be attainable. However, other values and/or ranges for the ratio W2:W1 are within the scope of the present disclosure.

In some implementations, increasing the width W1 directly increases a width of the cell contact landing 230-1 and/or the cell contact landing 230-2, thereby reducing a contact resistance between the cell contact landing 230-1 and/or the cell contact landing 230-2 and a contact structure that electrically couples to the semiconductive region. As an example, in some implementations, increasing the width W1 may reduce a contact resistance between the cell contact landing 230-1 (and/or the cell contact landing 230-2) with a contact structure by up to approximately 40%.

As another example, in some implementations, a width W3 of the insulative region 240 may be less than a width W4 between mid-region(s) 225 of adjacent active shaped semiconductive regions 205. As described in greater detail in connection with FIGS. 3-5B, the width W4 may be a biproduct of techniques used to trim the mid-region(s) 225. Using such techniques, an outer edge of the mid-region(s) 225 may be recessed from outer edges of the end region(s) 220 at a distance that is equivalent to a trim amount.

Although the description of FIG. 2B includes detailed dimensional properties and/or characteristics associated with the shaped semiconductive region 205-1, the shaped semiconductive region 205-2 may have substantially similar dimensional properties and/or characteristics and have a same approximate shape as the shaped semiconductive region 205-1.

As indicated above, FIGS. 2A and 2B are provided as an example. Other examples may differ from what is described with regard to FIGS. 2A and 2B.

As described in connection with FIG. 1 through FIG. 2B, in some implementations, an integrated assembly includes a shaped semiconductive region (e.g., the shaped semiconductive region 205-1). The shaped semiconductive region includes a first approximately trapezoidal end region (e.g., the end region 220-1), a second approximately trapezoidal end region (e.g., the trapezoidal end region 220-2), and a mid-region (e.g., the mid-region 225) extending between the first approximately trapezoidal end region and the second approximately trapezoidal end region. The mid-region may have a width (e.g., the width W1) in a direction that is less than a width of the first approximately trapezoidal end region and the second approximately trapezoidal end region in the direction (e.g., the width W2).

Additionally, or alternatively, in some implementations, an apparatus includes a memory array (e.g., the memory array 200). The memory array includes an active area (e.g., the shaped semiconductive region 205-1) including a cell contact region (e.g., the cell contact landing 230-1 that is part of the end region 220-1) and a bit contact region (e.g., the bit contact landing 235 that is part of the mid-region 225) extending from the cell contact region, wherein a ratio of a lateral width of the cell contact region to a lateral width of the bit contact region (e.g., the ratio W1:W2) is greater than approximately 1. The apparatus includes a shallow trench isolation region (e.g., the insulative region 240) along a contour of the active area and having an approximately linear sidewall along the cell contact region and an approximately linear sidewall along the bit contact region.

In these ways, the integrated assembly and/or the apparatus accommodates scaled down memory cells in high pattern density manufacturing. The introduction of the shaped active areas (e.g., the shaped semiconductive region 205) may maintain and/or increase widths of active areas and/or shallow trench isolation regions (e.g., the insulative region 240) within a memory array (e.g., the memory array 200), reduce stress-related defects during etching and filling processes used to form the memory array, and improve yield rates and device performance consistency in scaled memory architectures. Furthermore, the configuration of the active areas and the shallow trench isolation regions may facilitate electrical isolation and ensure higher reliability, thereby improving a quality and/or a reliability of the memory cell. As a result of improving the quality and/or the reliability, an amount of resources used to support a market consuming the semiconductor device (e.g., raw materials, semiconductor manufacturing tools, labor, and/or computing resources) is reduced.

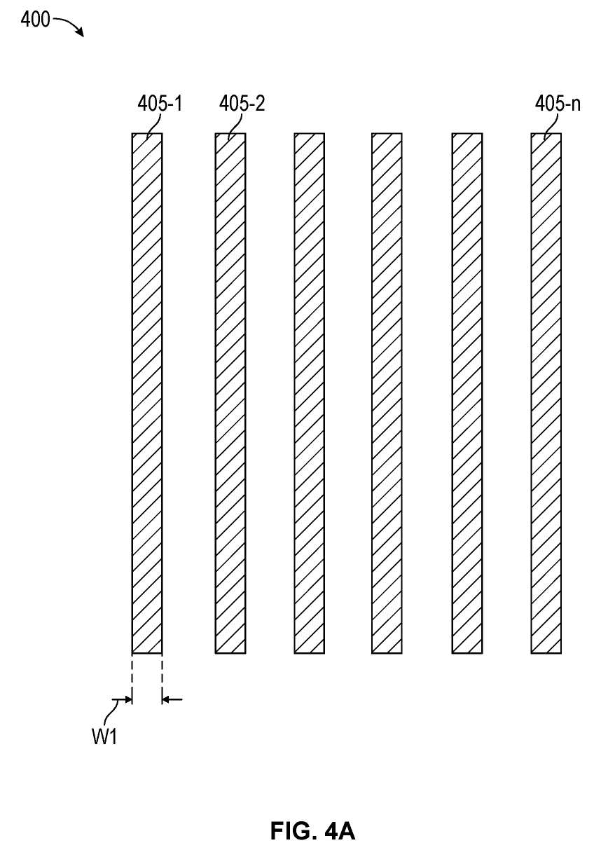

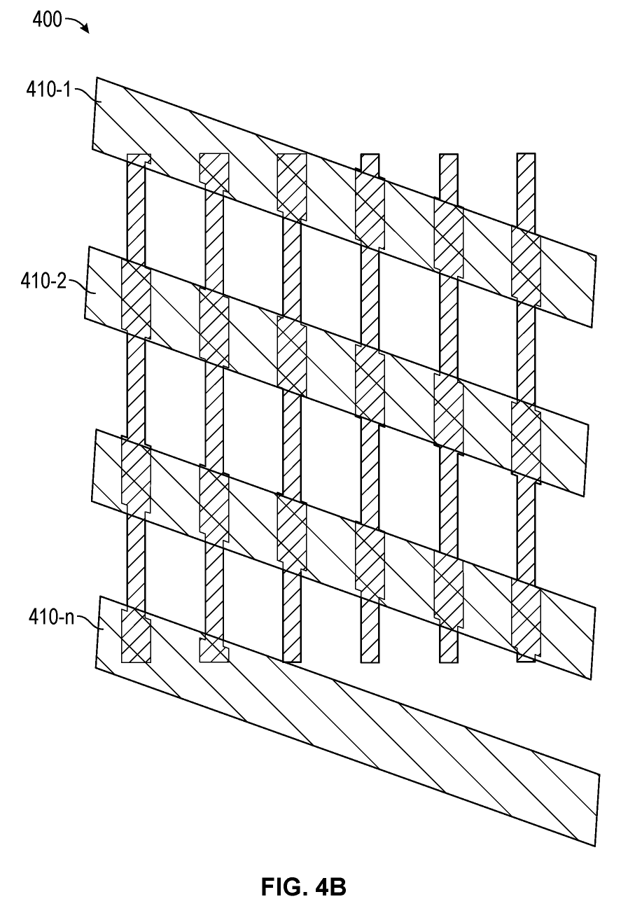

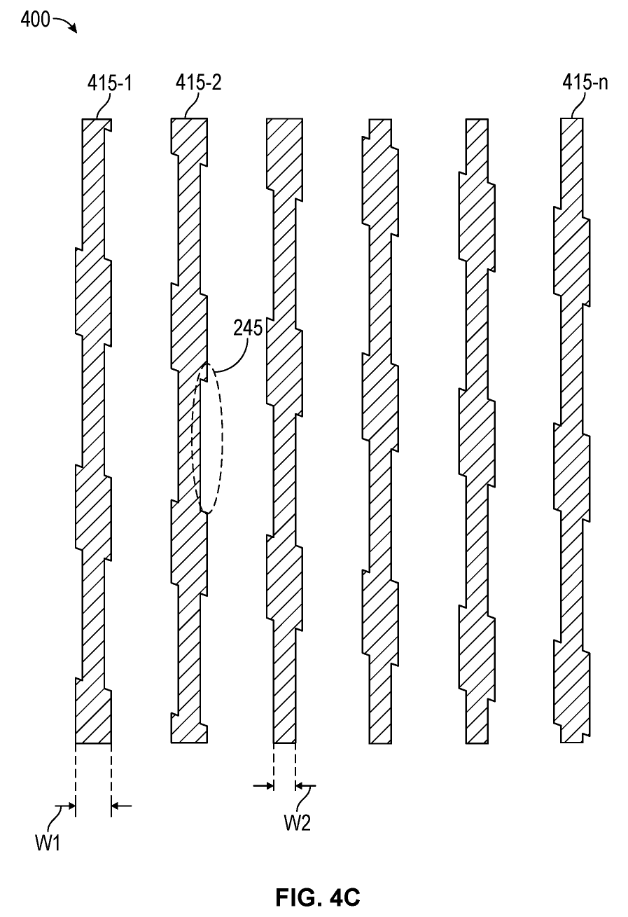

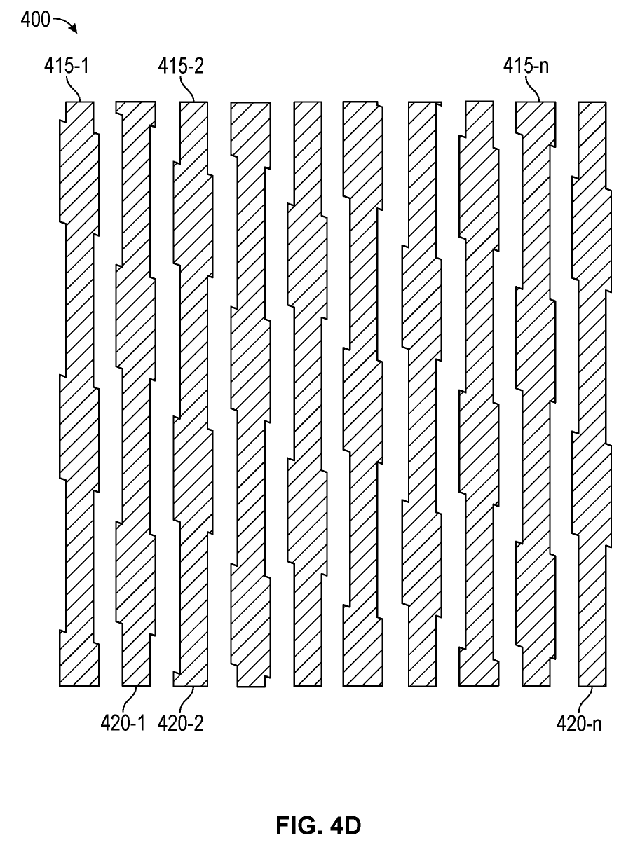

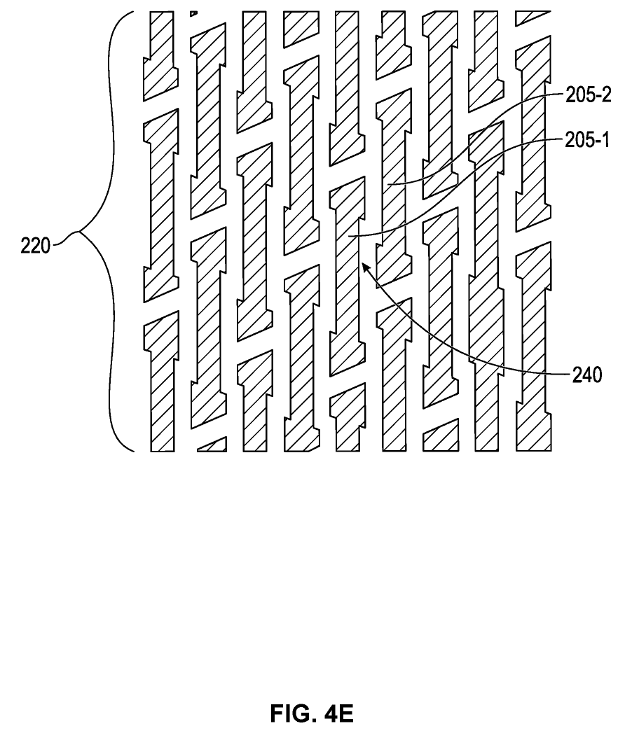

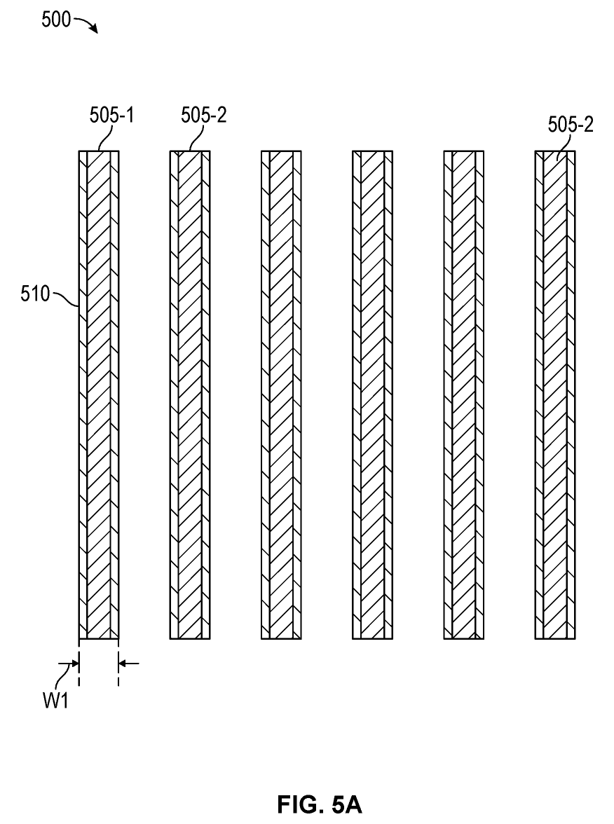

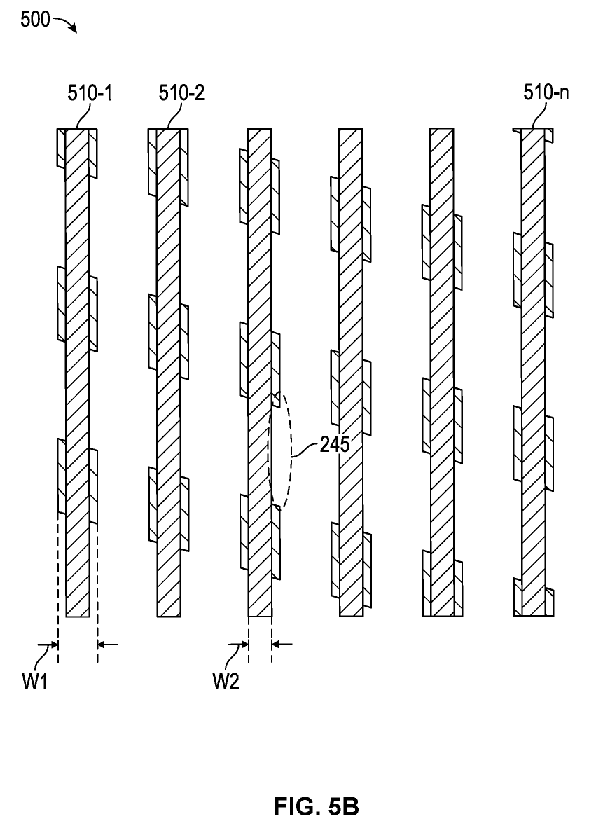

FIG. 3 is a flowchart of an example method 300 of forming an integrated assembly or memory device having an array of shaped semiconductive regions described herein (e.g., the array of shaped semiconductive regions 205). In some implementations, and as described in greater detail in connection with FIGS. 4A-5B, one or more process blocks of FIG. 3 may be performed by various semiconductor manufacturing equipment.

As shown in FIG. 3, the method 300 may include forming an array of first elongated semiconductive regions that have an alternating width pattern (block 310). As further shown in FIG. 3, the method 300 may include forming an array of second elongated semiconductive regions that have the alternating width pattern and that interleave with the first elongated semiconductive regions (block 320). As further shown in FIG. 3, the method 300 may include forming, from the first elongated semiconductive regions and the second elongated semiconductive regions, an array of active areas (e.g., the array of semiconductive regions 205) including opposing cell contact regions (e.g., the end regions 220 including the cell contact landings 230) having a first width (W1) in a direction and bit contact regions (e.g., the mid-region 225 including the bit contact landing 235) that extend between the opposing cell contact regions that have a second width (e.g., the width W2) that is less than the first width in the direction (block 330). As further shown in FIG. 3, the method 300 may include forming shallow trench isolation regions between the active areas (block 340).

The method 300 may include additional aspects, such as any single aspect or any combination of aspects described below and/or in connection with one or more other methods described elsewhere herein.

In a first aspect, forming the array of first elongated semiconductive regions includes forming an array of elongated linear semiconductive regions that have an approximately uniform width, and trimming portions of the elongated linear semiconductive regions to form the alternating width pattern.

In a second aspect, alone or in combination with the first aspect, trimming the portions includes forming an array of mask structures across the array of elongated portions, and removing material from unmasked portions of the array of elongated portions.

In a third aspect, alone or in combination with one or more of the first and second aspects, removing the material includes using an etching operation to remove the material.

In a fourth aspect, alone or in combination with one or more of the first through third aspects, forming the first elongated semiconductive regions includes forming a spacer layer along sidewalls of the first elongated semiconductive regions, and removing portions of the spacer layer as part of forming the alternating width pattern.

In a fifth aspect, alone or in combination with one or more of the first through fourth aspects, forming the second elongated semiconductive regions includes forming the second elongated semiconductive regions using a reverse pattern doubling process.

In a sixth aspect, alone or in combination with one or more of the first through fifth aspects, forming the array of array of active areas includes using an inverse hole pitch doubling process.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the array of shaped semiconductive regions 205, an integrated assembly that includes the array of shaped semiconductive regions 205, any part described herein of the array of shaped semiconductive regions 205, and/or any part described herein of an integrated assembly that includes the array of shaped semiconductive regions 205. For example, the method 300 may include forming one or more of the shaped semiconductive region 205-1, the shaped semiconductive region 205-2, and/or the insulative region 240.

FIGS. 4A-4E are diagrammatic views showing formation of an array of shaped semiconductive regions described herein (e.g., the array of shaped semiconductive regions 205) at stages of an example process 400 of forming the array. In some implementations, the process 400 described below in connection with FIGS. 4A through 4E may correspond to the method 300 and/or one or more blocks of the method 300. However, the process described below is an example, and other example processes may be used to form the shaped semiconductive region, an integrated assembly that includes the shaped semiconductive region, and/or one or more parts of the shaped semiconductive region and/or the integrated assembly.

As shown in FIG. 4A, the process 400 may include forming an array of elongated linear semiconductive regions 405-1 through 405-n that have an approximately uniform width (e.g., the width W1). As an example, in some implementations, forming the array may include a deposition tool forming (e.g., depositing, growing) a layer of a semiconductive material over and/or on a substrate (e.g., a silicon substrate). The semiconductive material may comprise, consist of, or consist essentially of silicon (e.g., polycrystalline silicon), a type III-V semiconductor material (e.g., gallium arsenide), or another suitable semiconductive material, among other examples. Forming the array may further include a combination of lithography and etch tools performing a series of patterning and etching operations to form the elongated linear semiconductive regions 405-1 through 405-n from the layer of semiconductive material.

As shown in FIG. 4B, the process 400 may include removing portions of the elongated semiconductive regions 405-1 through 405-n. As an example, in some implementations, removing (e.g., trimming or etching) the portions of the elongated semiconductive regions 405-1 through 405-n may include a set of lithography tools performing a series of patterning operations that form an array of mask structures 410-1 through 410-n (e.g., photoresist mask structures) across the elongated semiconductive regions 405-1 through 405-n. Removing the portions of the elongated semiconductive regions 405-1 through 405-n may further include an etch tool performing an etch operation that removes the portions from unmasked segments of the elongated semiconductive regions 405-1 through 405-n.

As shown in FIG. 4C, the process 400 may include removing the array 415 of mask structures 410-1 through 410-n to reveal an array of elongated semiconductive regions 415-1 through 415-n that have an alternating width pattern (e.g., the width W1 alternating with the width W2), where the elongated semiconductive regions 415-1 through 415-n each include one or more recessed portion(s) 245. In some implementations, removing the array 415 of mask structures 410-1 through 410-n includes an ash tool performing an ashing operation that removes the array 415 of mask structures 410-1 through 410-n.

As shown in FIG. 4D, the process 400 may include forming an array of elongated semiconductive regions 420-1 through 420-n that interleave with the array of elongated semiconductive regions 415-1 through 415-n. As an example, in some implementations, forming the elongated semiconductive regions 420-1 through 420-n includes using a reverse doubling patterning process, where a deposition tool forms (e.g., deposits, grows) a conformal liner along contours of the elongated semiconductive regions 415-1 through 415-n. The reverse doubling patterning process may further include a deposition tool forming (e.g., depositing, growing) the elongated semiconductive regions 420-1 through 420-n between the elongated semiconductive regions 415-1 through 415-n, and an etch tool removing the conformal liner layer to reveal the elongated semiconductive regions 420-1 through 420-n.

As shown in FIG. 4E, the process 400 may include forming the array of shaped semiconductive regions 205 (e.g., an array of active areas including the shaped semiconductive region 205-1 and the shaped semiconductive region 205-2) from the elongated semiconductive regions 415-1 through 415-n and the elongated semiconductive regions 420-1 through 420-n. As an example, in some implementations, forming the array of shaped semiconductive regions 205 may include using an inverse hole pitch doubling process, where a lithography tool may be used to pattern openings (e.g., gaps) across segments of the elongated semiconductive regions 415-1 through 415-n and across segments of the elongated semiconductive regions 420-1 through 420-n. The inverse hole pitch doubling process may further include an etch being used to remove material through the openings and “cut” the segments to separate and form the array of shaped semiconductive regions 205.

The process 400 may further include forming insulative regions 240 (e.g., shallow trench isolation regions) between the shaped semiconductive regions 205. As an example, in some implementations, forming the insulative regions 240 includes a deposition tool forming (e.g., depositing, growing) a layer of an insulative material between the shaped semiconductive regions 205.

As indicated above, the process steps described in connection with FIGS. 4A -4E are provided as examples. Other examples may differ from what is described with respect to FIGS. 4A-4E. The structure shown in FIGS. 4E may be equivalent to the array of shaped semiconductive regions 205 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

FIGS. 5A and 5B are diagrammatic views showing formation of an array of elongated semiconductive regions having an alternating width pattern at stages of an example process 500 of forming the array of elongated semiconductive regions. The process 500 described below in connection with FIGS. 5A and 5B may be substituted for one or more stages of the example process 400, and may correspond to the method 300 and/or one or more blocks of the method 300. However, the process described below is an example, and other example processes may be used to form the shaped semiconductive region, an integrated assembly that includes the shaped semiconductive region, and/or one or more parts of the shaped semiconductive region and/or the integrated assembly.

As shown in FIG. 5A, the process 500 may include forming an array of elongated linear semiconductive regions 505-1 through 505-n that have an approximately uniform width. As an example, in some implementations, forming the array may include a deposition tool forming (e.g., depositing, growing) a layer of a semiconductive material over and/or on a substrate (e.g., a silicon substrate). The semiconductive material may comprise, consist of, or consist essentially of silicon (e.g., polycrystalline silicon), a type III-V semiconductor material (e.g., gallium arsenide), or another suitable semiconductive material, among other examples. Forming the array may further include a combination of lithography and etch tools performing a series of patterning and etching operations to form the elongated linear semiconductive regions 505-1 through 505-n from the layer of semiconductive material.

Furthermore, and as shown in FIG. 5A, the process 500 may include forming a spacer layer 510 over and/or along surfaces of the elongated linear semiconductive regions 505-1 through 505-n. As an example, in some implementations, forming the spacer layer 510 may include a deposition tool forming (e.g., depositing, growing) a layer of a conformal, semiconductive material over and/or along the surfaces. The elongated structures may have the width W1.

As shown in FIG. 5B, the process 500 may include removing portions of the spacer layer 510 to form an array of elongated semiconductive regions 510-1 through 510-n that have an alternating width pattern (e.g., the width W1 alternating with the width W2), where the elongated semiconductive regions 510-1 through 510-n each include one or more recessed portion(s) 245. As an example, in some implementations, removing portions of the spacer layer 510 may include using a lithography tool and an etch tool to perform a series of patterning and etching operations that remove the portions.

In some implementations, the array of elongated semiconductive regions 510-1 through 510-n are substantially similar to the array of elongated semiconductive regions 415-1 through 420-n as described in connection with FIG. 4C. In such implementations, subsequent processing steps described in connection with FIGS. 4D and 4E may be used to form an array of shaped active areas (e.g., the array of shaped semiconductive regions 205).

Alternatively, in some implementations, the array of elongated semiconductive regions 510-1 through 510-n may be used as masking structures. In such implementations, the array of elongated semiconductive regions 510-1 through 510-n may be used as part of a pattern transferring process that forms an array of shaped active areas from a semiconductive layer below the array of elongated semiconductive regions 510-1 through 510-n.

As indicated above, the process steps described in connection with FIGS. 5A and 5B are provided as examples. Other examples may differ from what is described with respect to FIGS. 5A and 5B. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

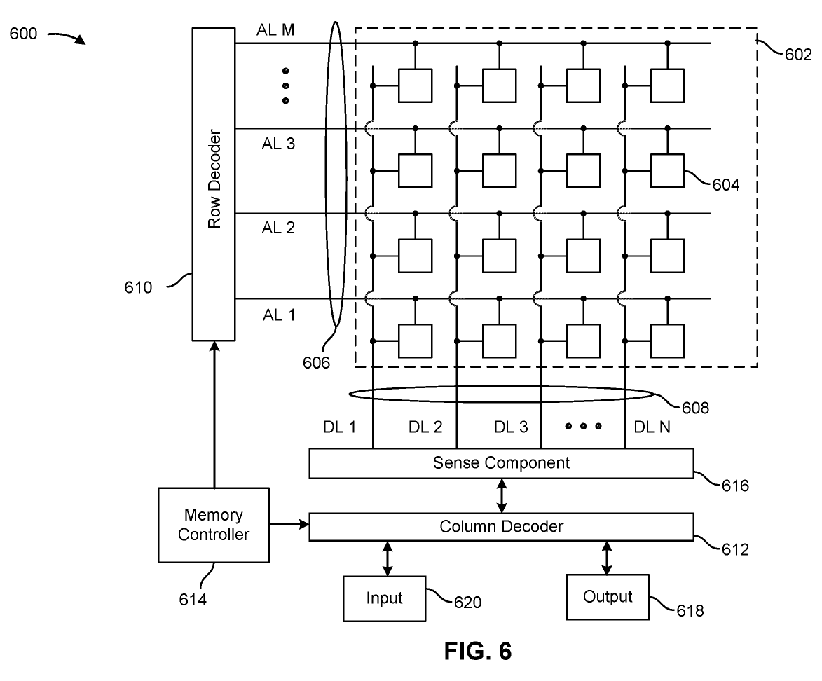

FIG. 6 is a diagrammatic view of an example memory device 600. The memory device 600 may include a memory array 602 that includes multiple memory cells 604. A memory cell 604 is programmable or configurable into a data state of multiple data states (e.g., two or more data states). For example, a memory cell 604 may be set to a particular data state at a particular time, and the memory cell 604 may be set to another data state at another time. A data state may correspond to a value stored by the memory cell 604. The value may be a binary value, such as a binary 0 or a binary 1, or may be a fractional value, such as 0.5, 1.5, or the like. A memory cell 604 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 604 by activating or selecting the appropriate access line 606 (shown as access lines AL 1 through AL M) and digit line 608 (shown as digit lines DL 1 through DL N). An access line 606 may also be referred to as a “row line” or a “word line,” and a digit line 608 may also be referred to a “column line” or a “bit line.” Activating or selecting an access line 606 or a digit line 608 may include applying a voltage to the respective line. An access line 606 and/or a digit line 608 may comprise, consist of, or consist essentially of a conductive material, such as a metal (e.g., copper, aluminum, gold, titanium, or tungsten) and/or a metal alloy, among other examples. In FIG. 6, each row of memory cells 604 is connected to a single access line 606, and each column of memory cells 604 is connected to a single digit line 608. By activating one access line 606 and one digit line 608 (e.g., applying a voltage to the access line 606 and digit line 608), a single memory cell 604 may be accessed at (e.g., is accessible via) the intersection of the access line 606 and the digit line 608. The intersection of the access line 606 and the digit line 608 may be called an “address” of a memory cell 604.

In some implementations, the logic storing device of a memory cell 604, such as a capacitor, may be electrically isolated from a corresponding digit line 608 by a selection component, such as a transistor. The access line 606 may be connected to and may control the selection component. For example, the selection component may be a transistor, and the access line 606 may be connected to the gate of the transistor. Activating the access line 606 results in an electrical connection or closed circuit between the capacitor of a memory cell 604 and a corresponding digit line 608. The digit line 608 may then be accessed (e.g., is accessible) to either read from or write to the memory cell 604.

A row decoder 610 and a column decoder 612 may control access to memory cells 604. For example, the row decoder 610 may receive a row address from a memory controller 614 and may activate the appropriate access line 606 based on the received row address. Similarly, the column decoder 612 may receive a column address from the memory controller 614 and may activate the appropriate digit line 608 based on the column address.

Upon accessing a memory cell 604, the memory cell 604 may be read (e.g., sensed) by a sense component 616 to determine the stored data state of the memory cell 604. For example, after accessing the memory cell 604, the capacitor of the memory cell 604 may discharge onto its corresponding digit line 608. Discharging the capacitor may be based on biasing, or applying a voltage, to the capacitor. The discharging may induce a change in the voltage of the digit line 608, which the sense component 616 may compare to a reference voltage (not shown) to determine the stored data state of the memory cell 604. For example, if the digit line 608 has a higher voltage than the reference voltage, then the sense component 616 may determine that the stored data state of the memory cell 604 corresponds to a first value, such as a binary 1. Conversely, if the digit line 608 has a lower voltage than the reference voltage, then the sense component 616 may determine that the stored data state of the memory cell 604 corresponds to a second value, such as a binary 0. The detected data state of the memory cell 604 may then be output (e.g., via the column decoder 612) to an output component 618 (e.g., a data buffer). A memory cell 604 may be written (e.g., set) by activating the appropriate access line 606 and digit line 608. The column decoder 612 may receive data, such as input from input component 620, to be written to one or more memory cells 604. A memory cell 604 may be written by applying a voltage across the capacitor of the memory cell 604.

The memory controller 614 may control the operation (e.g., read, write, re-write, refresh, and/or recovery) of the memory cells 604 via the row decoder 610, the column decoder 612, and/or the sense component 616. The memory controller 614 may generate row address signals and column address signals to activate the desired access line 606 and digit line 608. The memory controller 614 may also generate and control various voltages used during the operation of the memory array 602.

In some implementations, the memory device 600 includes the array of shaped semiconductive region(s) 205 and/or an integrated assembly that includes the array of shaped semiconductive region(s) 205. For example, the memory array 602 may include the semiconductive region 205-1 and the semiconductive region 205-2, where the insulative region 240 is between the shaped semiconductive region 205-1 and the shaped semiconductive region 205-2. Additionally, or alternatively, the memory cell 604 may include a memory cell described elsewhere herein.

As indicated above, FIG. 6 is provided as an example. Other examples may differ from what is described with respect to FIG. 6.

In some implementations, an integrated assembly includes a shaped semiconductive region, comprising: a first approximately trapezoidal end region; a second approximately trapezoidal end region; and a mid-region extending between the first approximately trapezoidal end region and the second approximately trapezoidal end region having a width in a direction that is less than a width of the first approximately trapezoidal end region and the second approximately trapezoidal end region in the direction.

In some implementations, an apparatus includes a memory array, comprising: an active area, comprising: a cell contact region; and a bit contact region extending from the cell contact region, wherein a ratio of a lateral width of the cell contact region to a lateral width of the bit contact region is greater than approximately 1; and a shallow trench isolation region along a contour of the active area and having an approximately linear sidewall along the cell contact region and an approximately linear sidewall along the bit contact region.

In some implementations, a method includes forming an array of first elongated semiconductive regions that have an alternating width pattern; forming an array of second elongated semiconductive regions that have the alternating width pattern and that interleave with the first elongated semiconductive regions; forming, from the first elongated semiconductive regions and the second elongated semiconductive regions, an array of active areas including opposing cell contact regions that have a first width in a direction and bit contact regions that extend between the opposing cell contact regions that have a second width that is less than the first width in the direction; and forming a shallow trench isolation region between the array of active areas.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a shaped semiconductive region, comprising:
a first approximately trapezoidal end region;
a second approximately trapezoidal end region; and
a mid-region extending between the first approximately trapezoidal end region and the second approximately trapezoidal end region having a width in a direction that is less than a width of the first approximately trapezoidal end region and the second approximately trapezoidal end region in the direction.

2. The integrated assembly of claim 1, wherein an orientation of the second approximately trapezoidal end region mirrors an orientation of the first approximately trapezoidal end region.

3. The integrated assembly of claim 1, further comprising:
an insulative region along the mid-region having an approximately linear sidewall.

4. The integrated assembly of claim 1, wherein the shaped semiconductive region is a first shaped semiconductive region, and further comprising:
a second shaped semiconductive region that is approximately parallel to the first shaped semiconductive region and that is staggered with respect to the first shaped semiconductive region.

5. The integrated assembly of claim 4, wherein the second shaped semiconductive region has a same approximate shape as the first shaped semiconductive region.

6. The integrated assembly of claim 5, wherein an insulative region is between the first shaped semiconductive region and the second shaped semiconductive region.

7. An apparatus, comprising:
a memory array, comprising:
an active area, comprising:
a cell contact region; and
a bit contact region extending from the cell contact region,
wherein a ratio of a lateral width of the cell contact region to a lateral width of the bit contact region is greater than approximately 1; and
a shallow trench isolation region along a contour of the active area and having an approximately linear sidewall along the cell contact region and an approximately linear sidewall along the bit contact region.

8. The apparatus of claim 7, wherein the bit contact region has an approximately rectangular shape.

9. The apparatus of claim 7, wherein the active area is an active area of an array of active areas that are staggered and each have a same, approximate shape.

10. The apparatus of claim 7, wherein the shallow trench isolation region occupies a recessed portion of the active area along the bit contact region.

11. The apparatus of claim 7, wherein the active area is a first active area and the bit contact region is a first bit contact region, and
wherein the cell contact region extends toward a second bit contact region of a second active area that is adjacent to the first bit contact region.

12. The apparatus of claim 11, wherein a portion of the second active area is recessed along the second bit contact region.

13. The apparatus of claim 7, further comprising:
a word line that extends across the active area between the cell contact region and the bit contact region, and
a digit line that extends across the active area and that is approximately orthogonal to the word line.

14. A method, comprising:
forming an array of first elongated semiconductive regions that have an alternating width pattern;
forming an array of second elongated semiconductive regions that have the alternating width pattern and that interleave with the first elongated semiconductive regions;
forming, from the first elongated semiconductive regions and the second elongated semiconductive regions, an array of active areas including opposing cell contact regions that have a first width in a direction and bit contact regions that extend between the opposing cell contact regions that have a second width that is less than the first width in the direction; and
forming a shallow trench isolation region between the active areas.

15. The method of claim 14, wherein forming the array of first elongated semiconductive regions includes:
forming an array of elongated linear semiconductive regions that have an approximately uniform width; and
trimming portions of the elongated linear semiconductive regions to form the alternating width pattern.

16. The method of claim 15, wherein trimming the portions includes:
forming an array of mask structures across the array of elongated portions; and
removing material from unmasked portions of the array of elongated portions.

17. The method of claim 16, wherein removing the material includes:
using an etching operation to remove the material.

18. The method of claim 14, wherein forming the first elongated semiconductive regions includes:
forming a spacer layer along sidewalls of the first elongated semiconductive regions; and
removing portions of the spacer layer as part of forming the alternating width pattern.

19. The method of claim 14, wherein forming the second elongated semiconductive regions includes:
forming the second elongated semiconductive regions using a reverse pattern doubling process.

20. The method of claim 14, wherein forming the array of array of active areas includes:
using an inverse hole pitch doubling process.
